(19) United States
(12) Patent Application Publication
(10) Pub. No.: US 2008/0149382 A1
(43) Pub. Date: Jun. 26, 2008

(54) METHOD OF INSPECTING PRINTED WIRING BOARD AND PRINTED WIRING BOARD

(75) Inventors: Jun Karasawa, Tokyo (JP); Daigo Suzuki, Yokohama-shi (JP); Sadahiro Tamai, Ome-shi (JP)

Correspondence Address: BLAKELY SOKOLOFF TAYLOR & ZAFMAN, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 11/951,055

(22) Filed: Dec. 5, 2007

(30) Foreign Application Priority Data
Dec. 26, 2006 (JP) 2006-353037

(51) Int. Cl. G01R 31/02; H05K 1/02

(52) U.S. Cl. 174/262; 324/537

(57) ABSTRACT

According to one embodiment, in a method of inspecting a printed wiring board, the printed wiring board which is provided with an outer-layer surface and an inner-layer surface is prepared for inspection. The printed wiring board includes a land provided on the outer-layer surface, a via ranging from the land to the inner-layer surface, and an inner layer pattern provided on the inner-layer surface, wherein the inner layer pattern is electrically connected to the via when a via shift in the printed wiring board is within a tolerance range. A conduction state between the land and the inner layer pattern is detected.

### CROSS-REFERENCE TO RELATED APPLICATIONS

This application is based upon and claims the benefit of priority from Japanese Patent Application No. 2006-353037, filed Dec. 27, 2006, the entire contents of which are incorporated herein by reference.

### BACKGROUND

1. Field

One embodiment of the invention relates to a printed wiring board and a method of inspecting a printed wiring board.

2. Description of the Related Art

In manufacturing multi-layered printed wiring boards, an inner-layer surface sometimes shifts from an outer-layer surface (this shift will be referred to as “via shift”). In this case, when a via for making an interlayer connection to a land on the inner-layer surface (hereafter, inner-layer land) is formed on the outer-layer surface, the via shifts with respect to the inner-layer land. When the via shifts with respect to the inner-layer land, Zaochi may occur.

“Zaochi” is an unwanted state where a part of the via is out of a target land, and the part of the via falls from the land. “Target land” is a land which is provided on the inner-layer surface and corresponds to the via. When the Zaochi occurs, a part of plating layer of the via is partially thinned, and voids are formed in the bump which is bonded to the via, i.e., poor bonding occurs. To secure the product quality of the printed wiring board, it is necessary to inspect whether or not the via shift is within a tolerable range in the manufacture process.

Jpn. Pat. Appln. KOKOKU Publication No. 63-4960 discloses a multilayer printed wiring board which is capable of electrically detecting such via shift. In the printed wiring board, a through-hole not connected to any of inner layer patterns is provided, and a detection pattern, which is disposed around the through-hole while being spaced therefrom by a predetermined distance, is provided on an inner layer to be inspected. In the printed wiring board, if the via shift is smaller than a predetermined quantity, the detection pattern is disconnected from the through-hole, and if the via shift is larger than the predetermined quantity, the detection pattern is conductive to the through-hole. Therefore, one can learn whether or not the via shift is within a tolerance range by checking a conduction state between the through-hole and the detection pattern.

A land on the inner-layer surface and a wiring pattern in the printed wiring board are generally formed by removing an unwanted part from a solid copper foil by an etching process. To form a detection pattern on the inner-layer surface as described in the patent publication referred to above, the detection pattern is formed, by an etching process, simultaneously with the land and the wiring pattern.

When a quantity of copper having been removed by the etching is large due to the manufacturing tolerance, the land is small and the distance between the through-hole and the detection pattern is large. In this case, although the land is small and a defect such as Zaochi occurs, the hole-pattern distance is large so that the detection pattern tends to be disconnected from the through-hole, and there is a fear that the product is erroneously determined to be acceptable. In other words, there is a fear that the inspection process fails to find some failures, for example, Zaochi defects.

On the other hand, when the quantity of copper having been removed by the etching is small due to the manufacturing tolerance, the land is large and the distance between the through-hole and the detection pattern is small. In this case, the distance is small although the land is large and no defect occurs. Accordingly, the detection pattern tends to be easily conductive to the through-hole, and there is a fear that the product is erroneously determined to be unacceptable. In other words, there is a fear that the product free from such a defect as Zaochi is erroneously determined to be unacceptable. Thus, in the case where the inspection method using such a detection pattern is used, when the manufacturing tolerance is large, there is a possibility that the inspection result does not accurately reflect the actual state of the product.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary plan view showing a printed wiring board according to a first embodiment of the present invention;

FIG. 2 is an exemplary cross-sectional view taken along line F2-F2 in the printed wiring board shown in FIG. 1;

FIG. 3 is an exemplary exploded perspective view showing the printed wiring board according to the first embodiment;

FIG. 4 is an exemplary cross-sectional view showing a test coupon of the printed wiring board according to the first embodiment when no via shift occurs;

FIG. 5 is an exemplary cross-sectional view showing the test coupon of the printed wiring board according to the first embodiment when a via shift occurs;

FIG. 6 is an exemplary perspective view showing in model form a laminating process of the printed wiring board according to the first embodiment;

FIG. 7 is an exemplary perspective view showing in model form a process for forming an outer layer pattern in the printed wiring board according to the first embodiment;

FIG. 8 is an exemplary perspective view showing a process of inspecting the printed wiring board according to the first embodiment;

FIG. 9 is an exemplary perspective view showing a process of inspecting the printed wiring board according to the first embodiment;

FIG. 10 is an exemplary perspective view showing a test coupon of a printed wiring board according to a second embodiment of the present invention;

FIG. 11 is an exemplary cross-sectional view showing a structure of the test coupon in the printed wiring board according to the second embodiment when viewed along the surface of an inner layer;

FIG. 12 is an exemplary perspective view showing a test coupon of a printed wiring board according to a third embodiment of the invention; and

FIG. 13 is an exemplary cross-sectional view showing a structure of the test coupon of the printed wiring board according to the third embodiment when viewed along the surface of an inner layer.

### DETAILED DESCRIPTION

Various embodiments according to the invention will be described hereinafter with reference to the accompanying drawings. In general, according to one embodiment of the invention, a method of inspecting a printed wiring board includes: preparing a printed wiring board which is provided with an outer-layer surface and an inner-layer surface, the printed wiring board including a land provided on the outer-layer surface, a via ranging from the land to the inner-layer surface, and an inner layer pattern provided on the inner-layer surface, wherein the inner layer pattern is electrically connected to the via when a via shift in the printed wiring board is within a tolerance range. A conduction state between the land and the inner layer pattern is detected.

According to one embodiment of the invention, A printed wiring board comprises: a land provided on an outer-layer surface; a via ranging from the land to an inner-layer surface; and an inner layer pattern provided on the inner-layer surface, wherein the inner layer pattern is electrically connected to the via when a via shift in the printed wiring board is within a tolerance range.

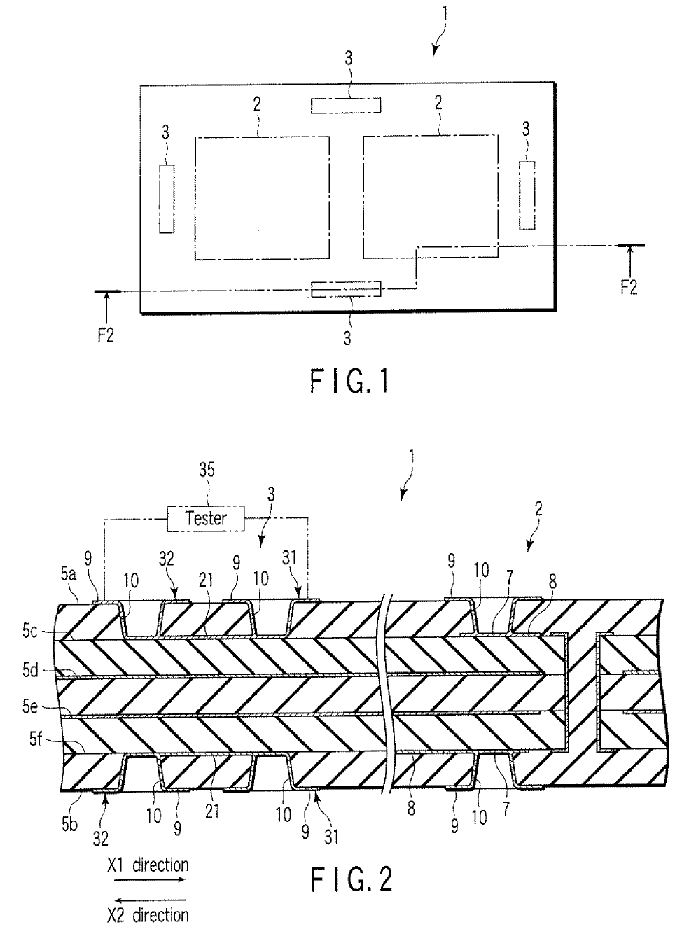

A printed wiring board 1 and a method of inspecting the printed wiring board 1 according to a first embodiment of the present invention will be described with reference to FIGS. 1 to 9.

FIG. 1 shows the whole printed wiring board 1. The printed wiring board 1 is a laminated plate (so-called work) as a manufacturing unit, for example, which contains therein a plurality of product portions 2 to be products. Each product portion 2 is cut out of the printed wiring board 1 in a subsequent step and is mounted as a system board on an electronic device.

The printed wiring board 1 contains test coupons 3, for example, four test coupons, which are located at the peripheral portions of the printed wiring board 1, which are located out of the product portions 2. The test coupons 3 are laminated integrally with the product portion 2, and are in the same laminating state as of the product portions 2. In the present specification, the “printed wiring board” involves a laminated plate on which a solder resist is not yet coated and which is not completed.

As shown in FIG. 2, the printed wiring board 1 is a multi-layered plate containing conductive layers, for example, six conductive layers. The printed wiring board 1 has two outer-layer surfaces 5a and 5b, and four inner-layer surfaces 5c, 5d, 5e and 5f on which the conductive layers are formed. Inner layer lands 7 are respectively formed on the inner-layer surfaces 5c and 5f of the product portion 2. Hereafter, the inner-layer surface 5c, on which the inner layer land 7 is provided, is taken up for explanation as one example of an inner-layer surface to be inspected, and the structure for inspecting an inner-layer misalignment of the inner-layer surface 5c with respect to the outer-layer surface 5a will be described in detail.

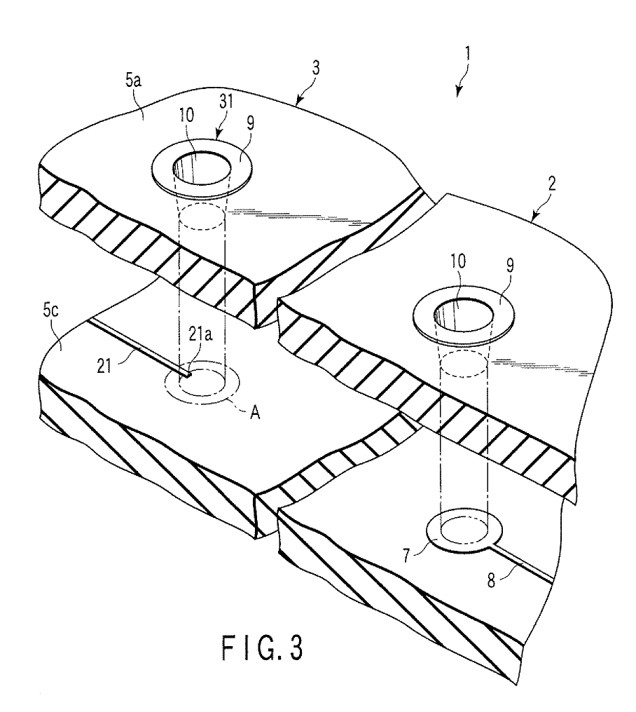

As shown in FIG. 3, the inner layer land 7 is formed on the inner-layer surface 5c of the product portion 2. The inner layer land 7 is electrically connected to an inner layer pattern 8 to be a part of a circuit of the system board. A land 9 is formed on the outer-layer surface 5a of the product portion 2. A via 10 connected to the inner layer land 7 is provided on the land 9. The land 9 and the inner layer land 7 are electrically interconnected through the via 10. When the via shift is not present in the printed wiring board 1, the center of the via 10 corresponds in position to the center of the inner layer land 7.

The land 9 and the via 10 are formed on the outer-layer surface 5a of each test coupon 3 as in the case of the product portion 2. That is, the via 10 ranges from the land 9 to the inner-layer surface 5c. An area A is set on the inner-layer surface 5c of the test coupon 3, while corresponding to the via 10. In this embodiment, the external shape of the area A is the same as that of the inner layer land 7 of the product portion 2. When the printed wiring board 1 does not suffer from the via shift, the center of the via 10 corresponds in position to the center of the area A. Therefore, when the via 10 of the test coupon 3 is within the area A, the via 10 of the product portion 2 is placed on the inner layer land 7.

In the opposite case where part of the via 10 of the test coupon 3 shifts out of the area A, part of the via 10 of the product portion 2 shifts out of the inner layer land 7. In the embodiment, the via 10 is a blind via hole. The word “via” used in the description of the invention involves also a through-hole passing through a plurality of layers.

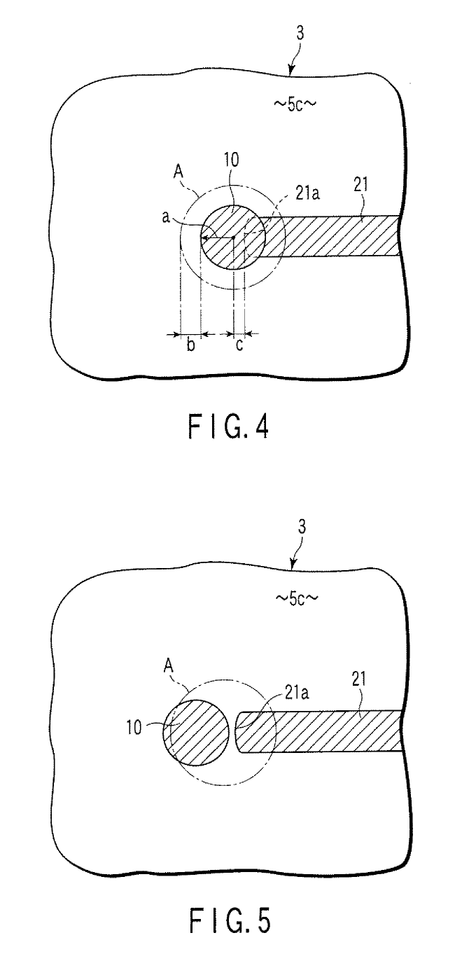

An inner layer pattern 21 is provided on the inner-layer surface 5c of the test coupon 3. In this embodiment, the inner layer pattern 21 is linear in shape. The inner layer pattern 21 extends from the outside of the area A to the via 10, and reaches the inside of the area A. As shown in FIG. 4, in this instance, the inner layer pattern 21 is formed so as to satisfy a relation defined by the following equation (1):

c=a×2−(a+b) (1)

where “a” represents a radius of the via 10, “b” represents a tolerable quantity of the via shift (i.e., difference between the radius of the area A and that of the via 10), and “C” represents a distance from the center of the area A to a tip 21a of the inner layer pattern 21.

In the case where the radius “a” of the via 10 is 60 μm and the tolerable quantity “b” of the via shift is 50 μm, the tip 21a of the inner layer pattern 21 is formed at a position located apart from the center of the area A by a distance of 10 μm. In other words, in the case where no via shift is present, the inner layer pattern 21 is formed partially overlapping with the via 10 by a length corresponding to the tolerable quantity “b” of the via shift.

As shown in FIG. 4, when the via shift in the printed wiring board 1 is within the tolerance range, the inner layer pattern 21 comes into contact with the via 10. In other words, the inner layer pattern 21 is electrically connected to the land 9. As shown in FIG. 5, the inner layer pattern 21 is out of the via 10 when the via shift in the printed wiring board 1 exceeds the tolerance range in the direction which is opposite to the direction in which the inner layer pattern 21 is provided. In other words, the inner layer pattern 21 is electrically disconnected from the land 9.

As shown in FIG. 2, the test coupon 3 is provided with two detection portions 31 and 32. Each of detection portions 31, 32 includes the land 9, the via 10 and the inner layer pattern 21. In one detection portion 31 (to be referred to as a first detection portion 31), the inner layer pattern 21 extends toward one via 10 in a direction X1 in FIG. 2. In the other detection portion 32 (to be referred to as a second detection portion 32), the inner layer pattern 21 extends toward the other via 10 in a direction X2 in FIG. 2.

The inner layer pattern 21 in the first detection portion 31 and the inner layer pattern 21 in the second detection portion 32 extend in directions which are different with respect to the vias 10. The direction X1 is different from the direction X2 by 180°. With such a structure, when the via shift, which exceeds the tolerable quantity “b” in the direction in which the inner layer pattern 21 is provided, occurs in the first detection portion 31, for example, the inner layer pattern 21 contacts with the via 10 in the first detection portion 31, on the other hand, the inner layer pattern 21 goes out of the via 10 in the second detection portion 32.

In the first embodiment, the inner layer patterns 21 in the first and second detection portions 31 and 32 are formed integral with each other. In other words, one inner layer pattern 21, which linearly extends, forms parts of the first and second detection portions 31 and 32.

A method of manufacturing the printed wiring board 1 will be described.

A core laminate plate having a solid copper foil layer is subjected to an etching process to remove unwanted copper and to form an inner layer pattern 21 on the test coupon 3. The inner layer pattern 21 is formed simultaneously with the inner layer land 7 and the inner layer pattern 8 of the product portion 2.

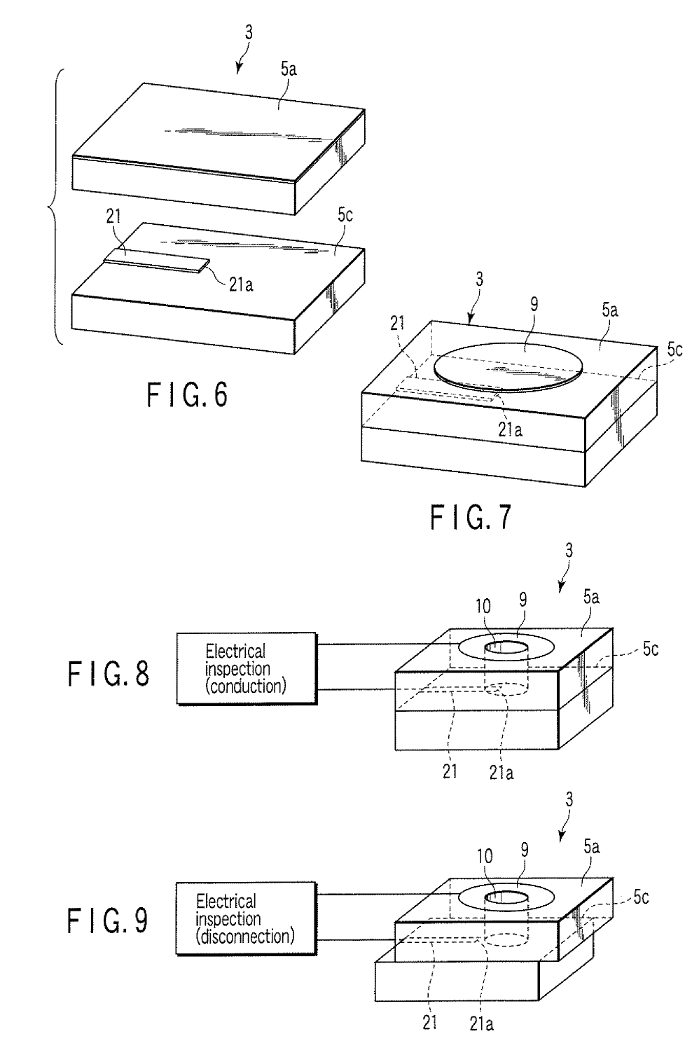

By the build-up process, an insulating layer having a solid copper foil layer is laminated on each of the obverse and reverse surfaces of the core laminate plate having the inner layer pattern 21 formed thereon, and lands 9 are respectively formed in the test coupon 3 and the product portion 2 by the etching process (FIGS. 6 and 7). Holes are formed in those lands 9 by the laser or drilling process, and the inner peripheral surface thereof is plated, whereby vias 10 are formed. As a result, the printed wiring board 1 to be inspected for the via shift is formed.

The printed wiring board 1, which has been found acceptable in the via shift inspection, is transferred to a subsequent step and the product portion 2 is cut out into a system board. The printed wiring board 1, which has been found unacceptable, is transferred to an analyzing step where manufacturing conditions or the like are reconsidered.

A method of inspecting the printed wiring board 1 will be described hereunder.

The printed wiring board 1 is prepared. A conduction state between the land 9 and the inner layer pattern 21 of each test coupon 3 in the printed wiring board 1 thus manufactured is detected. When the detection result shows conduction between the land 9 and the inner layer pattern 21, the via 10 is within the area A and the via shift is within the tolerance range. (FIG. 8).

When the detection result shows that the land 9 is disconnected from the inner layer pattern 21, part of the via 10 shifts out of the area A. In this case, it is estimated that the via shift of the printed wiring board 1 is out of the tolerance range and hence, the via 10 of the product portion 2 misregisters with the inner layer land 7 (FIG. 9).

The test coupon 3 of the first embodiment contains the two detection portions, first and second detection portions 31 and 32. The inner layer pattern 21 in the first detection portion 31 and the inner layer pattern 21 in the second detection portion 32 extend in directions opposite to each other. With provision of the two detection portions, even if the via 10 shifts to the side to which the inner layer pattern 21 extends in either of the first and second detection portions 31 and 32, and the inner layer pattern 21 thereof is conductive to the via 10, the inner layer pattern 21 is disconnected from the via 10 in the remaining detection portion. Thus, by detecting both the conduction states between the via 10 and the inner layer pattern 21 in the first detection portion 31 and between the via 10 and the inner layer pattern 21 in the second detection portion 32, the via shift of the printed wiring board 1 can be more accurately detected.

In the embodiment, one inner layer pattern 21 is commonly used for the first and second detection portions 31 and 32. When the via shift of the printed wiring board 1 is within the tolerance range, the land 9 of the first detection portion 31 is conductive to the land 9 of the second detection portion 32 by way of the inner layer pattern 21. When the via shift of the printed wiring board 1 is out of the tolerance range, the land 9 of the first detection portion 31 is disconnected from the land 9 of the second detection portion 32. Thus, the conduction states between the via 10 and the inner layer pattern 21 in the first detection portion 31 and between the via 10 and the inner layer pattern 21 in the second detection portion 32 can be checked by checking the conduction state between the land 9 in the first detection portion 31 and the land 9 in the second detection portion 32. Accordingly, the via shift of the printed wiring board 1 can be detected by a single conduction check.

Specifically, as shown in FIG. 2, a conduction state between the lands 9 of the first detection portion 31 and the second detection portion 32 is detected by measuring resistance between the lands 9 by using a tester 35, for example. The tester 35 may be directly connected at terminal pins to the lands 9 of the first and second detection portions 31 and 32 or may be connected to pads additionally formed and electrically connected to the lands 9.

The thus arranged method of inspecting the printed wiring board 1 is capable of highly accurately inspecting the via shift. In the case where the quantity of copper having been removed by etching is large due to the manufacturing error, the inner layer land 7 is small and the tip part of the inner layer pattern 21 is short. When the inner layer land 7 is small, Zaochi defects tend to occur. In this case, the inner layer pattern 21 is also small, the via 10 tends to be disconnected from the inner layer pattern 21, and the printed wiring board 1 tends to be determined to be unacceptable in the product inspection.

In the opposite case where the quantity of copper having been removed by etching is small due to the manufacturing error, the inner layer land 7 is large and the tip part of the inner layer pattern 21 is long. When the inner layer land 7 is large, Zaochi defects are less likely to occur. In this case, the inner layer pattern 21 is large. As a result, the inner layer pattern 21 is easy to be made conductive to the via 10 and the printed wiring board 1 tends to be determined to be acceptable.

When the printed wiring board 1 thus constructed is used, the inspection result frequently indicates an actual product state even if the manufacturing error is large. In other words, the possibility for the manufacturing error to adversely affect the acceptance/unacceptance decision is lessened. Namely, the possibility for the inspection process to fail to find Zaochi defects is lessened. Further, the possibility that defect-free products are determined to be unacceptable is lessened, and hence, the inspection of via shift is highly accurate. The production yield of the printed wiring board 1 thus constructed is therefore raised.

The inner layer pattern 21 is configured to be provided partially overlapping with the via 10 by a length corresponding to the tolerance quantity “b”, when the via shift is not present. By so doing, if a simple pattern is used for the inner layer pattern 21, it comes into contact with the via 10 when the via shift is within the tolerance range. When it is out of the tolerance range, it is disconnected from the via 10.

If the inner layer pattern 21 is linearly shaped, the pattern design is easy and its formation is simple. Further, also when the via shift in the printed wiring board 1 occurs in the line width direction of the inner layer pattern 21, its via shift can be detected.

The printed wiring board 1 is designed such that the two first and second detection portions 31 and 32 are provided, and the direction in which the inner layer pattern 21 extends toward the via 10 in the first detection portion 31 is opposite to the direction in which the inner layer pattern 21 extends toward the via 10 in the second detection portion 32. Even if, in one of these detection portions, the via 10 shifts in the direction in which the via 10 overlaps with the inner layer pattern 21, the via 10 is disconnected from the inner layer pattern 21 in the other detection portion. Therefore, it is possible to reliably detect the via shift. When the directions in which the inner layer pattern 21 extend in the first and second detection portions 31 and 32 differ by 180°, the detection of the via shift is more reliable.

In the case where the inner layer patterns 21 of the first and second detection portions 31 and 32 are formed with a single linearly extending inner layer pattern 21, when the via shift is within the tolerance range, the lands 9 of the first and second detection portions 31 and 32 are conductive to each other. By detecting the conduction state between the lands 9 of the first and second detection portions 31 and 32, the conductivity between the vias 10 and the inner layer pattern 21 in the first and second detection portions 31 and 32 can be checked in one operation. This feature contributes to enhancement of the inspection work efficiency.

Alternatively, separate inner layer patterns 21 are used for the inner layer pattern in the first and second detection portions 31 and 32, respectively. Through-holes or vias that are connected to the inner layer patterns 21 are provided, and conduction states between the through-holes or vias and the lands 9 are detected.

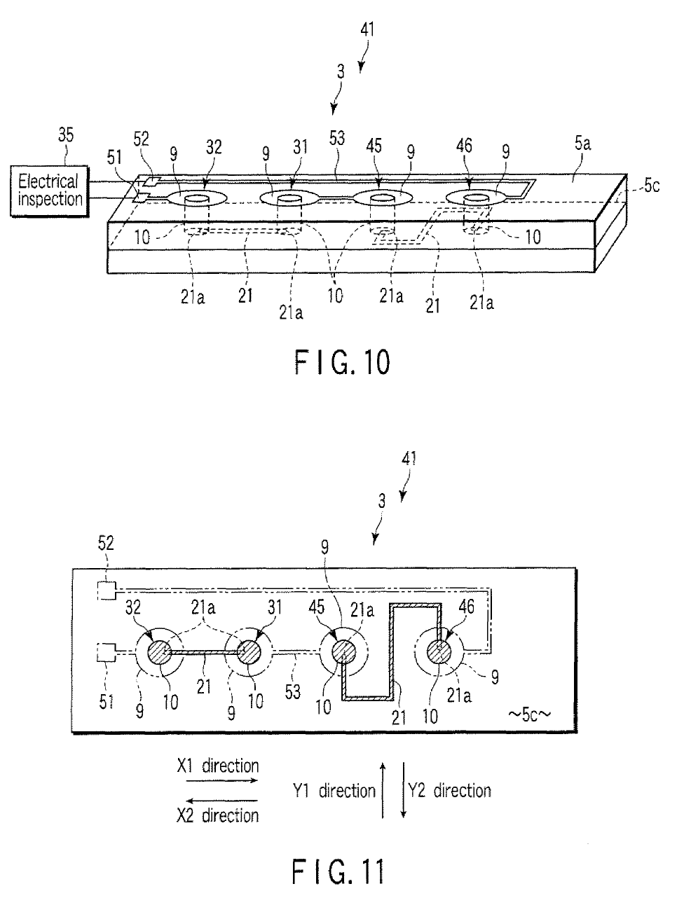

A printed wiring board 41 and a method of inspecting the printed wiring board 41 according to a second embodiment of the present invention will be described with reference to FIGS. 10 and 11. In the second embodiment, the portions having the same functions as in the printed wiring board 1 of the first embodiment are designated by like reference numerals and the description thereof will be omitted.

As shown in FIG. 10, first to fourth detection portions 31, 32, 45 and 46 are provided in the printed wiring board 41. The first to fourth detection portions 31, 32, 45 and 46 include each a land 9, a via 10 and an inner layer pattern 21. The inner layer patterns 21 of the first and second detection portions 31 and 32 are formed in an integral form. The inner layer patterns 21 of the third and fourth detection portions 45 and 46 are formed in an integral form.

As shown in FIG. 11, the inner layer pattern 21 extends in the direction X1 toward the via 10 in the first detection portion 31. The inner layer pattern 21 extends in the direction X2 toward the via 10 in the second detection portion 32. The directions X1 and X2 differ by 180°. In the third detection portion 45, the inner layer pattern 21 extends in a direction Y1 toward the via 10. In the fourth detection portion 46, the inner layer pattern 21 extends in a direction Y2 toward the via 10.

The directions Y1 and Y2 differ by 180°. The directions Y1 and X1 differ by 90°. Thus, the printed wiring board 41 is designed such that in the first to fourth detection portions 31, 32, 45 and 46, the inner layer patterns 21 extend toward the vias 10 in the directions which differ by 90°.

First and second pads 51 and 52 and a wiring pattern 53 are provided on a outer-layer surface 5a of the printed wiring board 41. The wiring pattern 53 electrically connects the first pad 51 and the land 9 of the first detection portion 31, the land 9 of the second detection portion 32 and the land 9 of the third detection portion 45, and the land 9 of the fourth detection portion 46 and the second pad 52. Thus, the wiring pattern 53 cooperates with the inner layer patterns 21 to electrically connect the lands 9 of the first to fourth detection portions 31, 23, 45 and 46 in series when the via shift is within the tolerance range.

A method of inspecting the printed wiring board 41 will now be described.

To start with, detection is made of a conduction state between the first and second pads 51 and 52 (i.e. conduction state of the wiring pattern 53) in the printed wiring board 41. When conduction is detected between the first and second pads 51 and 52, the via 10 is conductive to the inner layer pattern 21 in each of the first to fourth detection portions 31, 32, 45 and 46. In other words, the conduction between the first and second pads 51 and 52 indicates that the via shift in the printed wiring board 41 is within the tolerance range.

When the first and second pads 51 and 52 are disconnected from each other, the via 10 is disconnected from the inner layer pattern 21 in one or a plurality of sites in the first to fourth detection portions 31, 32, 45 ad 46. In other words, the disconnection indicates that the via shift of the printed wiring board 41 is out of the tolerance range.

The method of inspecting the printed wiring board 41 lessens the possibility that the inspection process fails to find Zaochi defects, and also lessens the possibility that defect-free products are determined to be unacceptable, and hence, highly accurate inspection of the via shift is possible, as in the case of inspecting the printed wiring board 1 of the first embodiment.

Where the inner layer patterns 21 extend toward the vias 10 in the directions that are different from one another by 90° in the four detection portions 31, 32, 45 and 46, the via shift in the printed wiring board 41 is detected in the two-dimensional direction and the via shift can be highly accurately inspected.

When the wiring pattern 53 electrically connecting the four detection portions 31, 32, 45 and 46 in series is provided, the via shift can be detected by merely detecting a conduction state of the wiring pattern 53. Alternatively, to detect the via shift, it suffices that conduction between the via 10 and the inner layer pattern 21 is detected in each of the detection portions 31, 32, 45 and 46 without checking the conduction state between the first and second pads 51 and 52.

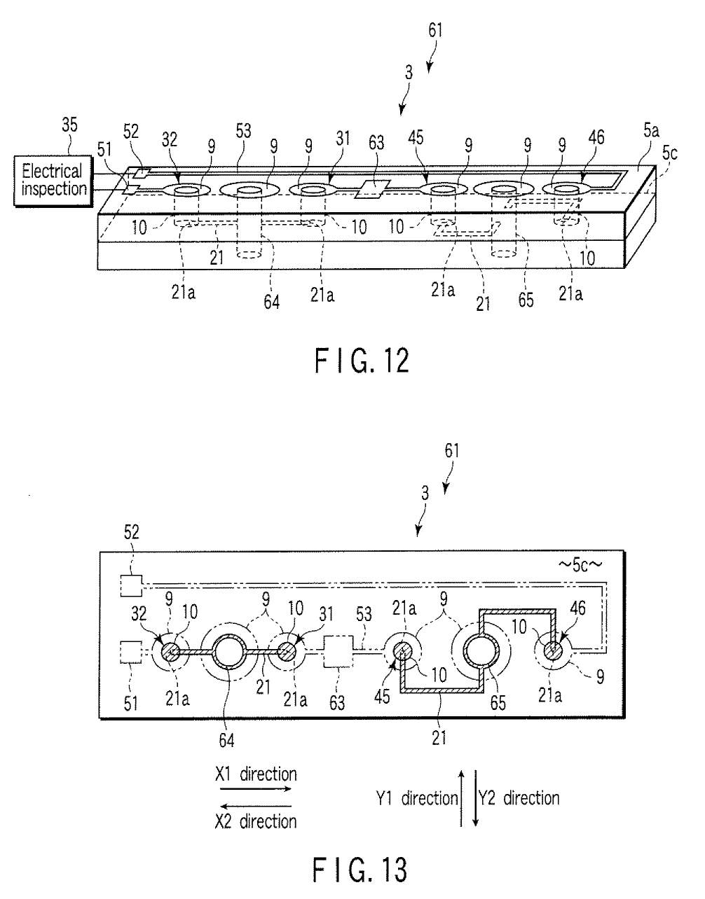

A printed wiring board 61 and a method of inspecting the printed wiring board 61 according to a third embodiment of the invention will be described with reference to FIGS. 12 and 13. In the third embodiment, the portions having the same functions as in the printed wiring boards 1 and 41 of the first and second embodiments are designated by Like reference numerals and the description thereof will be omitted.

As shown in FIGS. 12 and 13, a third pad 63 and first and second through-holes 64 and 65 are provided on the outer-layer surface 5a of the printed wiring board 61. The third pad 63 is provided at a mid position of the wiring pattern 53 ranging between the second detection portion 32 and the third detection portion 45. The first through-hole 64 is provided in association with the inner layer pattern 21 ranging between the first detection portion 31 and the second detection portion 32, and electrically connected to the inner layer pattern 21. The second through-hole 65 is provided in association with the inner layer pattern 21 ranging between the third and fourth detection portions 45 and 46, and electrically connected to the inner layer pattern 21.

A method of inspecting the printed wiring board 61 will now be described.

A conduction state between the first and second pads 51 and 52 in the printed wiring board 61 is first inspected as in the second embodiment. When the first and second pads 51 and 52 are disconnected from each other, the via 10 is disconnected from the inner layer pattern 21 in one or a plurality of sites in the first to fourth detection portions 31, 32, 45 and 46.

When the first and second pads 51 and 52 are disconnected from each other, conduction states between the pad 63 and the lands 9 of the four detection portions 31, 32, 45, 46 are further detected. Specially, a conduction state between the first pad 51 and the third pad 63 is detected. When the first pad 51 is conductive to the third pad 63, the via shift is present in the Y1 or Y2 direction. When the second pad 52 is conductive to the third pad 63, the via shift is present in the X1 or X2 direction.

Further, by detecting conduction states between the first pad 51 and the first through-hole 64, between the third pad 63 and the first through-hole 64, between the second pad 52 and the second through-hole 65, and between the third pad 63 and the second through-hole 65, one may learn the directions Y1, Y2, X1 and X2 of the via shift.

The method of inspecting the printed wiring board 61 lessens the possibility that the inspection process fails to find Zaochi defects, and also lessens the possibility that defect-free products are determined to be unacceptable, and hence, highly accurate inspection of the via shift is possible, as in the case of inspecting the printed wiring board 1 of the first embodiment.

Provision of the third pad 63 enables one to check the direction of the via shift, the direction X1 or X2 and direction Y1 or Y2. Provision of the first and second through-holes 64 and 65 enables one to check the direction of the via shift, the direction X1 or X2 and direction Y1 or Y2. In other words, the direction of the via shift can be electrically checked.

The first and second through-holes may be replaced with blind vias. While the printed wiring boards 1, 41 and 61 and the methods of inspecting those printed wiring boards according to the first to third embodiments have been described, it should be understood that the present invention is not limited to these printed wiring boards and inspection methods. The constituents of the first to third embodiments may be appropriately combined, if required, within the scope of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

What is claimed is:

1. A method of inspecting a printed wiring board, comprising:
preparing a printed wiring board which is provided with an outer-layer surface and an inner-layer surface, the printed wiring board including (i) a land provided on the outer-layer surface, (ii) a via ranging from the land to the inner-layer surface, and (iii) an inner layer pattern provided on the inner-layer surface, wherein the inner layer pattern is electrically connected to the via when a via shift in the printed wiring board is within a tolerance range; and
detecting a conduction state between the land and the inner layer pattern.

2. A method of inspecting a printed wiring board according to claim 1, wherein when the via shift is within the tolerance range, the inner layer pattern comes into contact with the via, and when the via shift is out of the tolerance range, the inner layer pattern is disconnected from the via.

3. A method of inspecting a printed wiring board according to claim 1, wherein when no said via shift is present, the inner layer pattern partially overlaps with the via by a length corresponding to a tolerable quantity of the via shift.

4. A method of inspecting a printed wiring board according to claim 1, wherein the inner layer pattern is linear in shape.

5. A method of inspecting a printed wiring board according to claim 4, wherein
the printed wiring board includes two detection portions each including the land, the via and the inner layer pattern,
a direction in which the inner layer pattern extends toward the via in one detection portion is different from that in which the inner layer pattern extends toward the via in the other detection portion, and
a conduction state between the land and the inner layer pattern in each of the two detection portions is detected.

6. A method of inspecting a printed wiring board according to claim 5, wherein
the inner layer pattern in the one detection portion and the inner layer pattern in the other detection portion are formed in an integral form, and
a conduction state between the lands of the two detection portions is detected.

7. A method of inspecting a printed wiring board according to claim 6, wherein
the printed wiring board includes four said detection portions,
the inner layer patterns extend toward the vias of the detection portions in directions being different from one another by 90° in the four detection portions, and
a conduction state between the land and the inner layer pattern in each of the four detection portions is detected.

8. A method of inspecting a printed wiring board according to claim 7, wherein
the printed wiring board includes a wiring pattern which cooperates with the inner layer patterns to electrically connect the lands of the four detection portions in series when the via shift is within the tolerance range, and
a conduction state of the wiring pattern is detected.

9. A method of inspecting a printed wiring board according to claim 8, wherein
the wiring pattern is provided on the outer-layer surface,
the printed wiring board includes a pad at a mid point on the wiring pattern connected to said plurality of lands, and
conduction states between the pad and the lands of the four detection portions are detected.

10. A printed wiring board comprising:
an outer-layer surface;
an inner-layer surface;
a land provided on the outer-layer surface;
a via ranging from the land to the inner-layer surface; and
a inner layer pattern provided on the inner-layer surface,
wherein the inner layer pattern is electrically connected to the via when a via shift in the printed wiring board is within a tolerance range.
